(19) United States
(12) Patent Application Publication
(10) Pub. No.: US 2009/0244968 A1
(43) Pub. Date: Oct. 1, 2009

(54) SEMICONDUCTOR MEMORY DEVICE INCLUDING MEMORY CELL HAVING CHARGE ACCUMULATION LAYER AND CONTROL GATE

(76) Inventor: Hiroshi MAEJIMA, Chigasaki-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/406,477

(22) Filed: Mar. 18, 2009

(30) Foreign Application Priority Data
Mar. 31, 2008 (JP) 2008-093642

(51) Int. Cl. G11C 16/04

(52) U.S. Cl. 365/185.03; 365/185.05; 365/185.11; 365/185.18

(57) ABSTRACT

A semiconductor memory device includes a select transistor, a memory cell transistor, a select gate line, a word line, and a row decoder. The memory cell transistor includes a charge accumulation layer and a control gate, and a current path one end of which is connected to a current path in the select transistor. The select gate line and word line are connected to a gate and the control gate of the select transistor and memory cell transistor. The row decoder includes a transfer circuit which transfers a voltage to the select gate line and includes a first switch including a first MOS transistor of a depression type. The first MOS transistor includes a current path one end of which is connected to the select gate line, and transfers a first voltage provided to the other end of the current path to the select gate line.

### CROSS-REFERENCE TO RELATED APPLICATIONS

This application is based upon and claims the benefit of priority from prior Japanese Patent Application No. 2008-093642, filed Mar. 31, 2008, the entire contents of which are incorporated herein by reference.

### BACKGROUND OF THE INVENTION

1. Field of the Invention

The present invention relates to a semiconductor memory device. The present invention relates to the configuration of a row decoder in, for example, a NAND flash memory.

2. Description of the Related Art

NAND flash memories are conventionally known as nonvolatile semiconductor memories. As a method of reading data from a NAND flash memory, a method of sensing current is known. Such a method is disclosed in, for example, PCT National Publication No. 2006-500727. The method allows data to be read for all bit lines at a time, enabling an increase in the speed of a read operation.

### BRIEF SUMMARY OF THE INVENTION

A semiconductor memory device according to an aspect of the present invention includes:

a select transistor;

a memory cell transistor including a stacked gate having a charge accumulation layer and a control gate, the memory cell transistor including a current path one end of which is connected to a data transfer line via a current path in the select transistor;

a select gate line connected to a gate of the select transistor;

a word line connected to the control gate of the memory cell transistor; and

a row decoder selecting the word line and the select gate line, the row decoder including a transfer circuit configured to transfer a voltage to the select gate line, the transfer circuit including a first switch including a first MOS transistor of a depression type, the first MOS transistor including a current path one end of which is connected to the select gate line, the first MOS transistor transferring a first voltage provided to the other end of the current path to the select gate line.

### BRIEF DESCRIPTION OF THE SEVERAL VIEWS OF THE DRAWING

FIG. 1 is a block diagram of a NAND flash memory according to an embodiment of the present invention;

FIG. 2 is a sectional view of a memory cell array according to the embodiment;

FIG. 3 is a graph showing the threshold distribution of a memory cell according to the embodiment;

FIG. 4 is a circuit diagram of a row decoder according to the embodiment;

FIG. 5 is a timing chart of various signals during read in the NAND flash memory according to the embodiment;

FIG. 6 is a circuit diagram of a row decoder according to the embodiment;

FIG. 7 is a graph showing the relationship between a read level and a voltage VCGR in the flash memory according to the embodiment;

FIG. 8 is a timing chart of various signals during programming in the NAND flash memory according to the embodiment;

FIG. 9 is a circuit diagram of a row decoder according to the embodiment;

FIG. 10 is a timing chart of various signals during erasure in the NAND flash memory according to the embodiment;

FIGS. 11 to 13 are circuit diagrams of a row decoder according to the embodiment; and

FIGS. 14 and 15 are circuit diagrams of transfer circuits according to a first modification and a second modification, respectively, of the embodiment.

### DETAILED DESCRIPTION OF THE INVENTION

A semiconductor memory device according to an embodiment of the present invention will be described citing a NAND flash memory by way of example.

### <Configuration of the NAND Flash Memory>

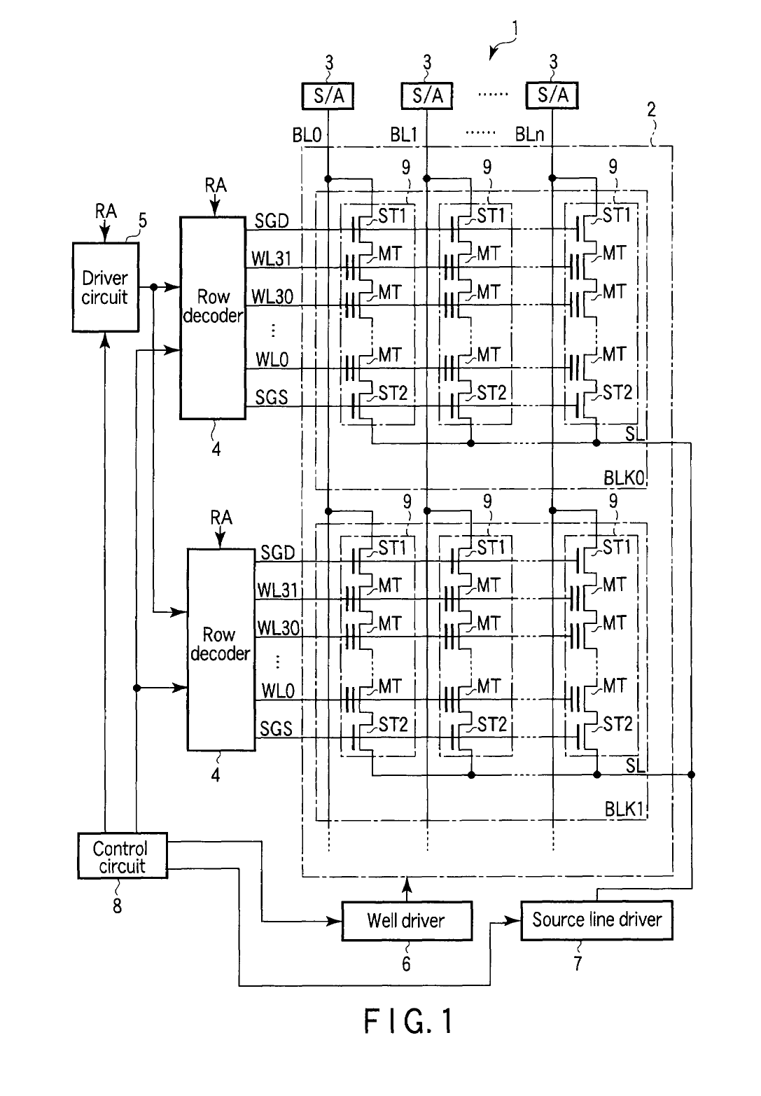

As shown in FIG. 1, a NAND flash memory 1 includes a memory cell array 2, sense amplifiers 3, row decoders 4, a driver circuit 5, a well driver 6, a source line driver 7, and a control circuit 8.

First, the memory cell array 2 will be described. The memory cell array 2 includes a plurality of memory cell units BLK0 to BLKm (m is a natural number of at least two). If the memory cell units BLK0 to BLKm are not distinguished from one another below, the memory cell units BLK0 to BLKm are collectively referred to as memory blocks BLK. Each of the memory cell units BLK includes n (n is a natural number of at least 1) memory cell units.

Each of the memory cell units 9 includes, for example, 32 memory cell transistors MT and select transistors ST1 and ST2. The memory cell transistor MT includes a stacked gate structure having a charge accumulation layer (for example, a floating gate) formed on a semiconductor substrate with a gate insulating film interposed therebetween and a control gate formed on the charge accumulation layer with an inter-gate insulating layer interposed therebetween. The number of the memory cell transistors MT is not limited to 32 but may be 8, 16, 64, 128, 256, or the like; no limitation is imposed on the number of the memory cell transistors MT. The adjacent memory cell transistors MT share a source and a drain. The memory cell transistors MT are arranged between the select transistors ST1 and ST2 so that current paths in the memory cell transistors MT are connected together in series. A drain of one of the series-connected memory cell transistors MT which is located at one end of the arrangement of the memory cell transistors MT is connected to a source of the select transistor ST1. A source of one of the series-connected memory cell transistors MT which is located at the other end of the arrangement is connected to a drain of the select transistor ST2.

Control gates of the memory cell transistors MT on the same row are connected commonly to one of word lines WL0 to WL31. Gates of the select transistors ST1 on the same row are connected commonly to a select gate line SGD. Gates of the select transistors ST2 on the same row are connected commonly to a select gate line SGS. For simplification of description, the word lines WL0 to WL31 are sometimes simply referred to as word lines WL. Sources of the select transistors ST2 are connected commonly to a source line SL. Not both select transistors ST1 and ST2 are required, and one of the select transistors ST1 and ST2 may be omitted provided that the remaining select transistor enables any of the memory cell units 9 to be selected.

In the memory cell array 2 configured as described above, drains of the select transistors ST1 in the memory cell units 9 on the same column are connected commonly to the same one of bit lines BL0 to BLn (n is a natural number). The bit lines BL0 to BLn are also sometimes simply referred to as the bit lines BL. That is, the bit line BL connects the memory cell units 9 in a plurality of memory blocks BLK together. On the other hand, the word lines WL and the select gate lines SGD and SGS connect the memory cell units 8 in the same memory block BLK together. Additionally, the memory cell units 9 included in the memory cell array 2 are connected to the same source line SL.

Furthermore, data is written to the plurality of memory cell transistors MT connected to the same word line WL at a time. This unit is called a page. Data is erased from the memory cell units 11 in the same memory block BLK at a time. That is, the memory block BLK is an erase unit.

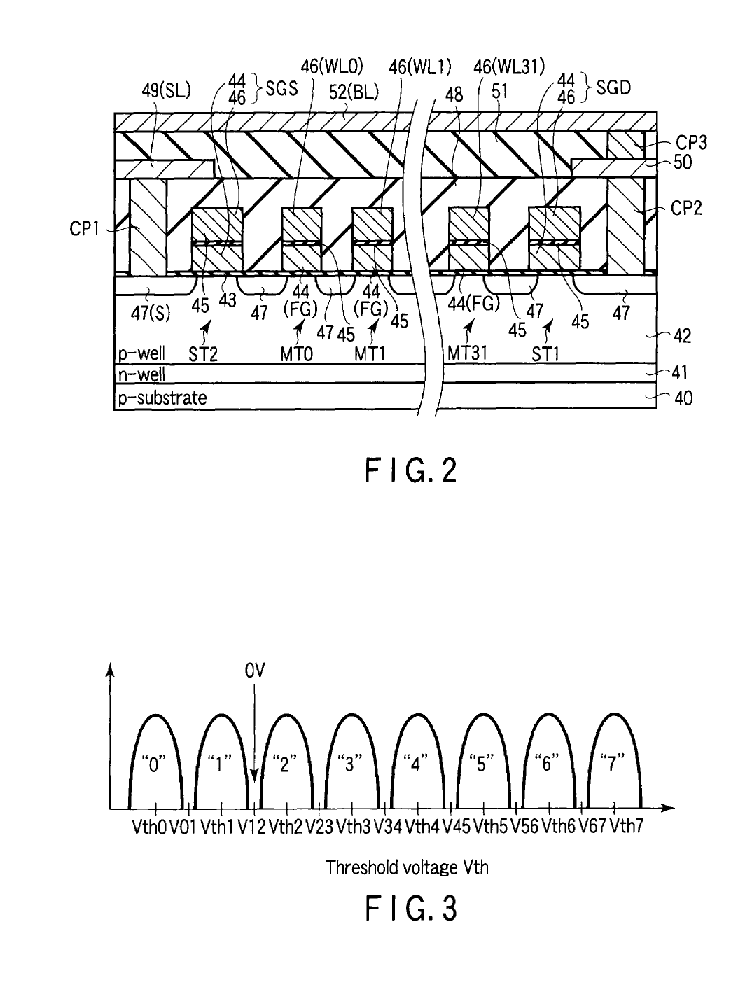

Now, the configuration of the memory cell unit 9, provided in the memory cell array 2, will be described with reference to FIG. 2. FIG. 2 is a sectional view of the memory cell unit 10 taken along a bit line direction of the memory cell unit 9.

As shown in FIG. 2, an n-type well region 41 is formed in a surface region of a p-type semiconductor substrate 40. A p-type well region 42 is formed in a surface region of the n-type well region 41. A gate insulating film 43 is formed on the p-type well region 42. Gate electrodes of the memory cell transistors MT and the select transistors ST1 and ST2 are formed on the gate insulating film 43. The gate electrodes of the memory cell transistors MT and the select transistors ST1 and ST2 each have a polycrystalline silicon layer 44 formed on the gate insulating film 43, an inter-gate insulating film 45 formed on the polycrystalline silicon layer 44, and a polycrystalline silicon layer 46 formed on the inter-gate insulating film 45. The inter-gate insulting film 45 is formed of, for example, a silicon oxide film, or an ON film, an NO film, or an ONO film which is a stacked structure of a silicon oxide film and a silicon nitride film, or a stack structure including any of the silicon oxide film, the ON film, the NO film, and the ONO film, or a stack structure of a TiO₂, HfO₂, Al₂O₃, HfAlOₓ, or HfAlSi film, and silicon oxide film or a silicon nitride film. The gate insulating film 43 functions as a tunnel insulating film.

In the memory cell transistor MT, the polycrystalline silicon layer 44 functions as a floating gate (FG). On the other hand, the polycrystalline silicon layers 46 arranged adjacent to each other in a direction orthogonal to the bit lines are connected together and function as a control gate (word line WL). In the select transistors ST1 and ST2, the polycrystalline silicon layers 44 and 46 arranged adjacent to each other in a word line direction are connected together. The polycrystalline silicon layers 44 and 46 thus function as the select gate line SGS or SGD. Alternatively, the polycrystalline silicon layers 44 alone may function as the select gate line. In this case, the potential of the polycrystalline silicon layers 46 in the select transistors ST1 and ST2 are set at a constant value or in a floating state. An n⁺-type impurity diffusion layer 47 is formed in a surface of the semiconductor substrate 40 between the gate electrodes. The impurity diffusion layer 47 is shared by the adjacent transistors and functions as a source (S) or a drain (D). An area between the source and the adjacent drain functions as a channel region through which electrons migrate. The gate electrode, the impurity diffusion layer 47, and the channel region form a MOS transistor making up the memory cell transistor MT or the select transistor ST1 or ST2.

An interlayer insulating film 48 is formed on the semiconductor substrate 40 so as to cover the memory cell transistors MT and the select transistors ST1 and ST2. A contact plug CP1 is formed in the interlayer insulating film 48 so as to reach the impurity diffusion layer (source) 47 of the source-side select transistor ST2. A metal wiring layer 49 connected to the contact plug CP1 is formed on the interlayer insulating film 48. The metal wiring layer 49 functions as a part of the source line SL. Furthermore, a contact plug CP2 is formed in the interlayer insulating film 48 so as to reach the impurity diffusion layer (drain) 47 of the drain-side select transistor ST1. A metal wiring layer 50 connected to the contact plug CP2 is formed on the interlayer insulating film 48.

An interlayer insulating film 51 is formed on the interlayer insulating film 48 so as to cover the metal wiring layers 49 and 50. A contact plug CP3 is formed in the interlayer insulating film 51 so as to reach the metal wiring layer 50. A metal wiring layer 52 connected to a plurality of the contact plugs CP3 is formed on the interlayer insulating film 51. The metal wiring layer 52 functions as the bit line BL.

The plurality of memory cell units 9 included in the memory cell array 2 are formed on the same well region 42.

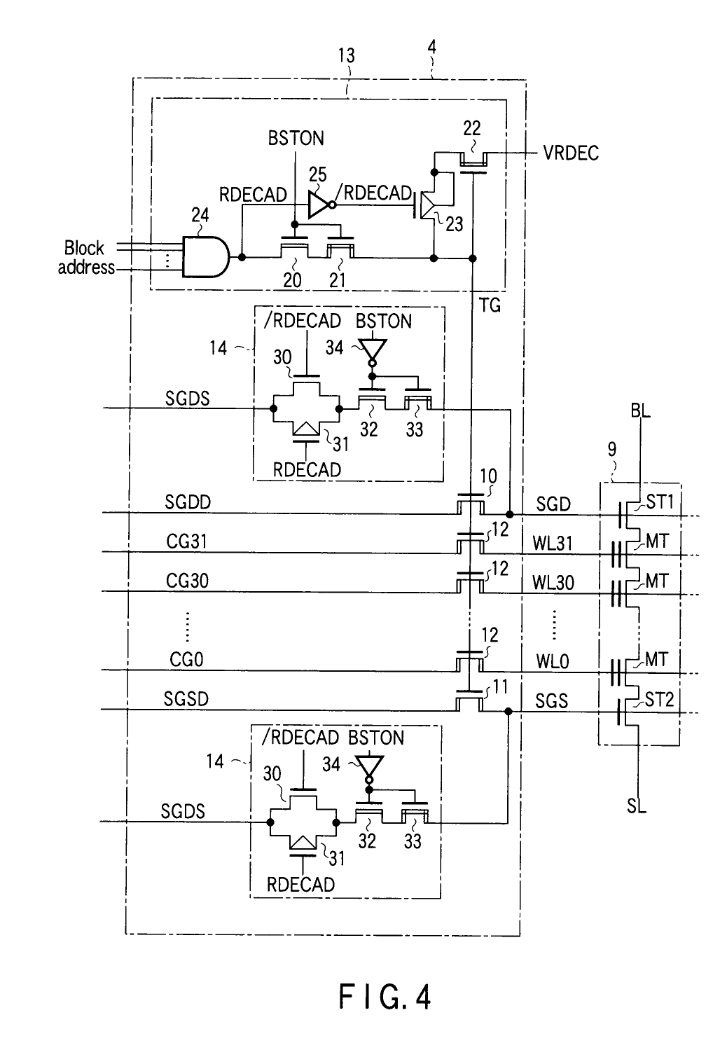

Now, the threshold distributions of the memory cell transistor MT will be described with reference to FIG. 3. In FIG. 3, the axis of abscissa indicates a threshold voltage Vth. The axis of ordinate indicates the presence probability of the memory cell transistor MT.

As shown in FIG. 3, each memory cell transistor MT can hold data of 8 levels (3 bit data). That is, the memory cell transistor MT can hold eight types of data of “0”, “1”, “2”, “3”, . . . , “7” in order of increasing threshold voltage Vth. A threshold voltage Vth0 for the “0” data in the memory cell transistor MT is Vth0<V01. A threshold voltage Vth1 for the “1” data is V01<Vth1<V12. A threshold voltage Vth2 for the “2” data is V12<Vth2<V23. A threshold voltage Vth3 for the “3” data is V23<Vth3<V44. A threshold voltage Vth4 for the “4” data is V44<Vth4<V45. A threshold voltage Vth5 for the “5” data is V45<Vth5<V56. A threshold voltage Vth6 for the “6” data is V56<Vth6<V67. A threshold voltage Vth7 for the “7” data is V67<Vth7.

For example, the voltage V12 is 0V. That is, the threshold voltages Vth0 and Vth1 for the “0” data and the “1” data have negative values. The threshold voltages Vth2 to Vth7 for the “2” and “7” data have positive values. A voltage V(i−1)i for “i” data (i is one of 1 to 7) is hereinafter referred to as the “read level” of the “i” data. That is, the voltage V01 is the read level of the “1” data. The voltage V12 is the read level of the “2” data. For the “1” to “7” data, the read level of the “1” data has a negative value, the read level of the “2” data is zero, and the read levels of the data larger than the “2” data have positive values.

The read level corresponding to 0V is not limited to V12 but may be the voltage V23, V44, or V01. Furthermore, the data that can be held by the memory cell transistor MT is not limited to the 8 levels. For example, the data may be 2 levels (1 bit data), 4 levels (2 bit data), 16 levels (4 bit data), or the like.

Referring back to FIG. 1, the configuration of the flash memory 1 will further be described. For data read, each of the sense amplifiers 3 senses and amplifies data read from the memory cell transistor MT onto the bit line BL. In this case, the sense amplifiers 3 sense currents flowing through the respective bit lines BL to determine the data on all the bit lines at a time. For data write, the sense amplifiers 3 transfer write data to the respective bit lines BL.

The row decoders 4 are provided for the respective memory blocks BLK. Based on an externally provided row address RA, the row decoder 43 applies voltages to the select gate lines SGD and SGS and the word lines WL connected to the corresponding memory block BLK during a data write operation, a data read operation, and a data erase operation.

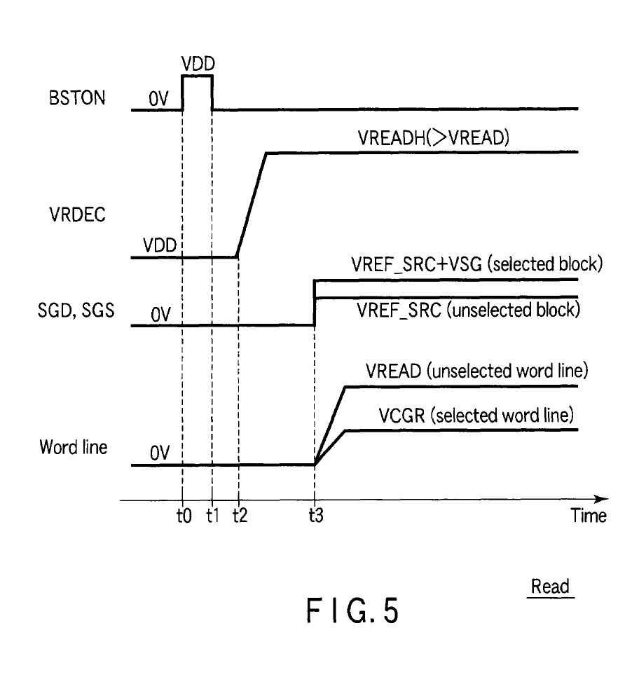

The configuration of the row decoder 4 will be described with reference to FIG. 4. As shown in FIG. 4, the row decoder 4 includes MOS transistors 10 to 12, a block decoder 13, and transfer circuits 14.

The MOS transistor 10 is an enhancement n-channel MOS transistor of a high withstand voltage type provided in association with the select gate line SGD. Thus, the MOS transistor 10 has a positive threshold. One end of a current path in the MOS transistor 10 is connected to the corresponding select gate line SGD. The other end of the current path is connected to a signal line SGDD.

The MOS transistor 11 is an enhancement n-channel MOS transistor of the high withstand voltage type provided in association with the select gate line SGS. One end of a current path in the MOS transistor 11 is connected to the corresponding select gate line SGS. The other end of the current path is connected to a signal line SGSD.

The MOS transistors 12 are enhancement n-channel MOS transistors of the high withstand voltage type provided in association with the word lines WL0 to WL31, respectively. One end of a current path in each of the MOS transistors 12 is connected to the corresponding one of the word lines WL0 to WL31. The other end of the current path is connected to a corresponding one of signal lines CG0 to CG31. If the signal lines CG0 to CG31 are not distinguished from one another below, the signal lines CG0 to CG31 are simply referred to as the signal lines CG.

In the same row decoder 4, gates of the MOS transistors 10 to 12 are connected to the same control line TG.

The block decoder 13 receives and decodes an externally provided row address, particularly an externally provided block address. The block address indicates the memory block BLK included in the memory cell array 2 and including the memory cell transistor MT to be subjected to data write, data read, or data erasure. The block decoder 13 applies a voltage to the control line TG according to the result of decoding of the block address to turn on or off the MOS transistors 10 to 12. As shown in FIG. 4, the block decoder 13 includes MOS transistors 20 to 23, an AND gate 24, and an inverter 25.

The AND gate 24 performs an AND operation on the bits of the externally provided block address. Thus, in the row decoder 4 corresponding to the memory block BLK indicated by the block address, the AND gate 24 outputs an “H” level. In the other row decoders 4, the AND gate 24 outputs an “L” level. An output signal from the AND gate 24, that is, the decoding result for the block address, is hereinafter referred to as a signal RDECAD. The AND gate 24 uses, for example, an internal voltage VDD (about 2.5V) as a high voltage-side power supply voltage, and uses 0V as a low voltage-side power supply voltage. That is, the potential of an output node of the AND gate 24 is VDD when the “H” level is output, and is 0V when the “L” level is output.

The MOS transistor 20 is a depression n-channel MOS transistor of a low withstand voltage type. Thus, the threshold of the MOS transistor 20 is at most 0V. One end of a current path in the MOS transistor 20 is connected to the output node of the AND gate 24. A signal BSTON is provided to a gate of the MOS transistor 20. The signal BSTON is input to the MOS transistor 20 when address information is loaded into the block decoder 44. The signal BSTON will be described below in detail.

The MOS transistor 21 is a depression n-channel MOS transistor having a higher withstand voltage than the MOS transistor 20. One end of a current path in the MOS transistor 21 is connected to the other end of the current path in the MOS transistor 20. The other end of the current path is connected to the signal line TG. The signal BSTON is provided to a gate of the MOS transistor 21.

The inverter 25 inverts the signal RDECAD. An output from the inverter 25 is hereinafter referred to as a signal /RDECAD.

The MOS transistor 23 is an enhancement p-channel MOS transistor of the above-described high withstand voltage type. One end of a current path in the MOS transistor 23 is connected to the control line TG. The other end of the current path is connected to a back gate. The signal /RDECAD is input to a gate of the MOS transistor 23.

The MOS transistor 22 is a depression n-channel MOS transistor of the above-described high withstand voltage type. A voltage VRDEC is provided to one end of a current path in the MOS transistor 22. The other end of the current path is connected to the other end of the current path in the MOS transistor 23. A gate of the MOS transistor 22 is connected to the control line TG. The voltage VRDEC exhibits a value required for each of the data write operation, the data read operation, and the data erase operation.

In the block decoder 13 configured as described above, when the block address matches the corresponding memory block BLK, the MOS transistors 22 and 23 are turned on to apply the voltage VRDEC to the control line TG. For the data write, VRDEC=VPGMH is set. For the data read, VRDEC=VREADH is set. For the data erasure, VRDEC=VDD is set. As a result, the MOS transistors 10 to 12 are turned on. The voltage VPGMH and VREADH are high positive voltages obtained by raising the voltage VDD. These voltages will be described below.

Now, still referring to FIG. 4, the transfer circuits 14 will be described. Each of the transfer circuits 14 is provided in association with a corresponding one of the select gate lines SGD and SGS. The transfer circuit 14 includes MOS transistors 30 to 33 and an inverter 34. The inverter 34 inverts the signal BSTON.

The MOS transistor 30 is an enhancement n-channel MOS transistor of the low withstand voltage type. The MOS transistor 31 is an enhancement p-channel MOS transistor of the low withstand voltage type. One end of a current path in each of the MOS transistors 30 and 31 is connected to a signal line SGDS. The other ends of the current paths in the MOS transistors 30 and 31 are connected together. The signals /RDECAD and RDECAD are input to gates of the MOS transistors 30 and 31, respectively.

The MOS transistor 32 is a depression n-channel MOS transistor of the low withstand voltage type. One end of a current path in the MOS transistor 32 is connected to both the other ends of the MOS transistors 30 and 31. An output signal (=/BSTON) from the inverter 34 is input to a gate of the MOS transistor 32.

The MOS transistor 33 is a depression n-channel MOS transistor having a higher withstand voltage than the MOS transistors 30 to 32. One end of a current path in the MOS transistor 33 is connected to the other end of the current path in the MOS transistor 32. The other end of the current path is connected to the select gate line SGD or SGS. The output signal (=/BSTON) from the inverter 34 is input to a gate of the MOS transistor 33.

In the transfer circuit 14 configured as described above, when the block address matches the corresponding memory block BLK, the MOS transistors 30 and 31 are turned off. On the other hand, when the block address does not match the corresponding memory block BLK, the MOS transistors 30 and 31 are turned on to transfer the required voltages to the select gate lines SGD and SGS through the signal line SGDS. Furthermore, as described above, the MOS transistors 30 to 32 have a lower withstand voltage than the MOS transistor 33. In other words, the film thickness of a gate insulating film in each of the MOS transistors 30 to 32 is smaller than that in the MOS transistor 33.

Referring back to FIG. 1, the configuration of the flash memory 1 will further be described. The driver circuit 5 receives and decodes an externally provided row address, particularly an externally provided page address. The page address indicates a page (word line WL) included in the memory cell array 2 and including the memory cell transistor MT to be subjected to data write, data read, or data erasure. The driver circuit 5 applies voltages to the signal lines CG0 to CG31, SGDD, SGSD, and SGDS according to the result of decoding of the page address.

The driver circuit 5 includes select gate line drivers, word line drivers, and an SGDS driver (none of the drivers are shown in the drawings). The word line drivers are provided for the signal lines CG0 to CG31, respectively, to apply voltages to the signal lines CG0 to CG31 according to the decoding result for the page address. The select gate line drivers are provided for the signal lines SGDD and SGSD, respectively, to apply voltages required for the data write, read, and erasure, respectively, to the signal lines SGDD and SGSD. The SGDS driver is provided in association with the signal line SGDS to apply voltages required for the data write, read, and erasure, respectively, to the signal lines SGDD and SGSD. The voltages applied to the signal lines CG0 to CG31, SGDD, SGSD, and SGDS by the drivers will be described below.

The well driver 6 applies a voltage to the well region 42 in which the memory cell array 2 is formed. That is, the well driver 6 provides a back gate bias for the memory cell transistor MT. For the data read, the well driver 6 applies a voltage VREF_SRC (positive voltage) to the well region 42. For the data write, the well driver 6 applies 0V to the well region 42. For the data erasure, the well driver 6 applies an erase voltage VERA (high positive voltage, for example, 20V) to the well region 42.

The source line driver 7 provides a voltage to the source line SL. For the data read, the source line driver 7 applies the voltage VREF_SRC (positive voltage) to the source line SL. That is, for the read, the source line SL is set to the same potential as that of the well region 42.

The control circuit 8 receives an externally provided command and an externally provided address. Based on the received command and address, the control circuit 8 controls the operation of the above-described circuit block based on the various instructions. Furthermore, the control circuit 8 includes a sequencer to control a series of processing (sequence) in each of the data write operation, the data erase operation, and the data read operation. The control circuit 8 also instructs a voltage generation circuit (not shown in the drawings) to generate various required voltages.

### <Operation of the NAND Flash Memory 1>

Now, the data read, programming, and erase operations in the NAND flash memory 1 configured as described above will be described focusing particularly on the operation of the row decoder 4. The memory block BLK including the memory cell transistor MT to be subjected to data read, programming, or erasure is hereinafter referred to as the selected memory block BLK. The memory blocks BLK not including this memory cell transistor MT are called the unselected memory blocks BLK.

### <Data Read Operation>

First, the data read operation will be described. The description below also applies to verification performed during the data read and erase operations. The write operation is performed by repeating a data programming operation and a data verify operation. The programming operation generates a potential difference between the control gate 46 and channel of the memory cell transistor MT to inject electrons into the charge accumulation layer 44 by Fowler-Nordheim (FN) tunneling. The verify operation reads data from the programmed memory cell transistor MT to determine whether or not the threshold voltage of the memory cell transistor MT has a desired value.

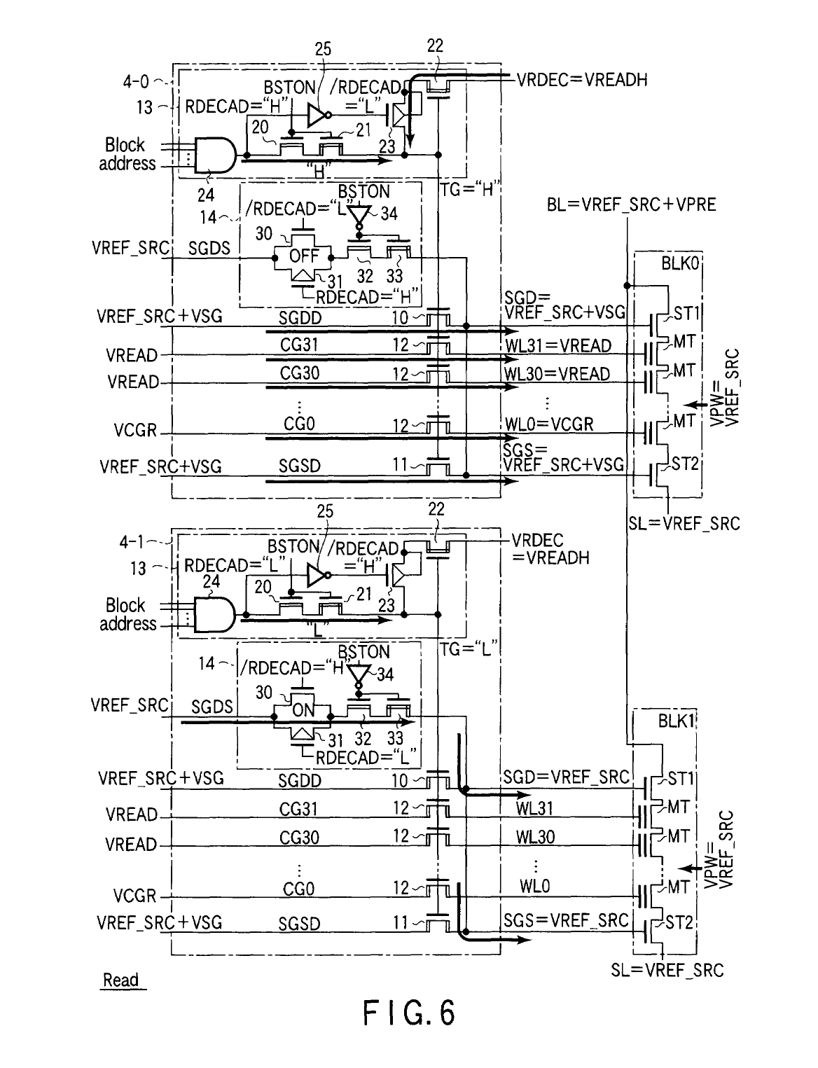

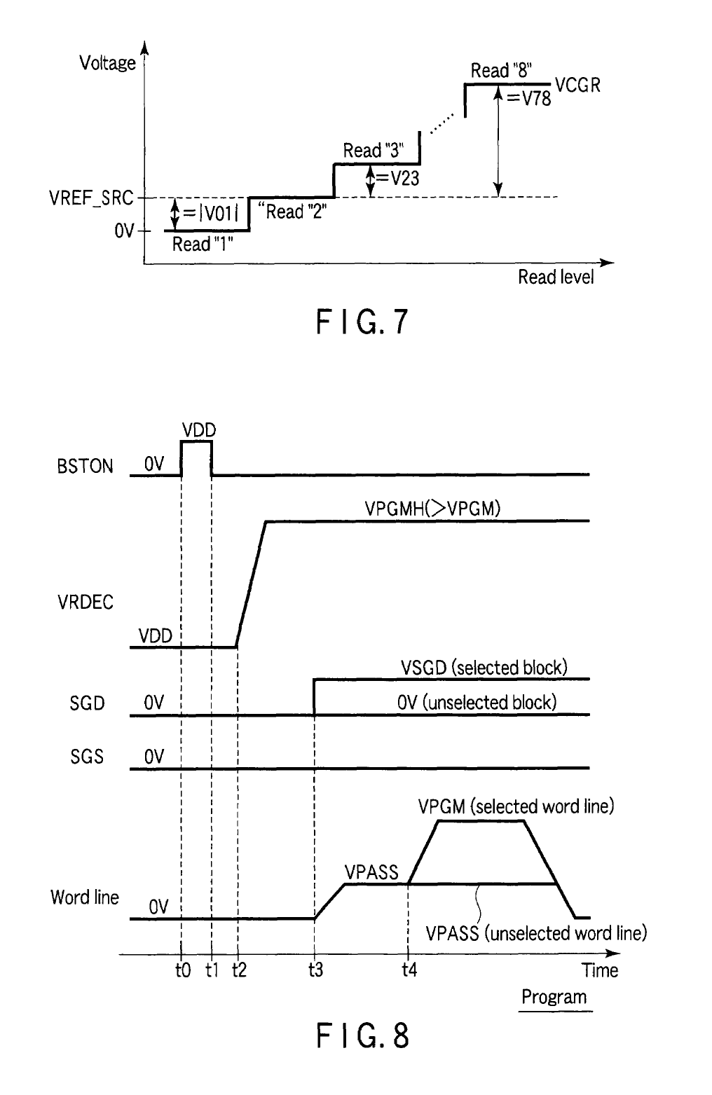

The data read operation will be described with reference to FIGS. 5 and 6. FIG. 5 is a timing chart showing variations in the potentials of the signal BSTON, the voltage VRDEC, the select gate lines SGD and SGS, and the word line WL during the read operation. FIG. 6 is a circuit diagram of the row decoder 4 during the read operation. For simplification, in the description below, the memory cell array 2 has two memory blocks BLK0 and BLK1, and data is read from the memory cell transistors MT connected to the word line WL0 of the memory block BLK0 (the word line WL0 is selected), by way of example. Furthermore, the row decoders 4 corresponding to the memory blocks BLK0 and BLK1 are hereinafter referred to as the row decoders 4-0 and 4-1. Moreover, because of space limitations, FIG. 6 shows only one transfer circuit 14 for each of the row decoders 4-0 and 4-1.

To read data, the sense amplifier 3 precharges the bit line BL to set the potential of the bit line BL to (VREF_SRC+VPRE). The source line driver 7 and the well driver 6 apply the voltage VREF_SRC to the source line SL and the well region 42, respectively.

The row decoder 4-0, corresponding to the selected memory block BLK0, and the row decoder 4-1, corresponding to the unselected memory block BLK1, will be described below.

First, the row decoder 4-0, corresponding to the selected memory block BLK0, will be described. At time to in FIG. 5, the block decoder 13 decodes the block address. Then, since the block address matches the memory block BLK0, to which the row decoder 4-0 corresponds, the AND gate 24 outputs the signal RDECAD=“H” level (for example, VDD). Thus, the signal /RDECAD=“L” level (for example, 0V) is set to turn on the MOS transistor 23. Furthermore, the control circuit 8 sets the signal BSTON=“H” level (for example, VDD). Setting BSTON=“H” turns on both the n-channel MOS transistors 20 and 21. Thus, the signal RDECAD is transferred to the signal line TG to set the signal line TG=“H” level (for example, VDD). Moreover, since the voltage VRDEC=VDD, the MOS transistor 22 is turned on. As a result, VRDEC=VDD is transferred to the signal line TG via the current paths in the MOS transistors 22 and 23. Thus, the MOS transistors 10 to 12 are turned on.

In the transfer circuit 14, the signal RDECAD=“H” and the signal /RDECAD=“L”. Thus, the MOS transistors 30 and 31 are turned off. Consequently, the select gate lines SGD and SGS are electrically disconnected from the signal line SGDS. The transfer circuit subsequently operates similarly. During the read operation, the select gate lines SGD and SGS are disconnected from the signal line SGDS.

Then, at time t1, BSTON=“L” is set to turn off the MOS transistors 20 and 21. However, the MOS transistors 22 and 23 remain on. Consequently, the signal line TG maintains the “H” level (VDD).

Then, at time t2, the control circuit 8 sets VRDEC=VREADH. The voltage VREADH enables the MOS transistors 12 to transfer the voltage VREAD. The voltage VREAD turns on the memory cell transistor MT regardless of data held by the memory cell transistor MT. That is, the voltage VREAD is higher than a voltage Vth7 in FIG. 3. VREADH is higher than VREAD at least by the threshold of the MOS transistors 22, 23, and 12. Setting VRDEC=VREADH sets the signal line TG=VREADH.

Then, at time t3, the driver circuit 5 applies a voltage VCGR to the signal line CG0, the voltage VREAD to the signal lines CG1 to CG31, while applying a voltage (VREF_SRC+VSG) to the signal lines SGDD and SGSD. The driver circuit 5 further applies the voltage VREF_SRC (which is the same as the voltage of the source line SL) to the signal line SGDS. The voltage VCGR is applied to the memory cell transistor MT to be subjected to the read. The voltage VCGR varies depending on the data to be read. The voltage (VREF_SRC+VSG) enables the select transistors ST1 and ST2 to be turned on.

Then, since TG=VREADH, the MOS transistors 10 and 11 transfer the voltage (VREF_SRC+VSG) to the select gate lines SGD and SGS, respectively. The MOS transistors 12 transfer VCGR to the word line WL0, while transferring VREAD to the word lines WL1 to WL31.

As a result, in the memory block BLK0, the memory cell transistors MT connected to the unselected word lines WL1 to WL31 are turned on to form a channel. The select transistors ST1 and ST2 are also turned on. The memory cell transistors MT are electrically connected to the bit line BL and the source line SL.

When the memory cell transistors MT connected to the selected word line WL0 are turned on, the bit line BL and the source line SL become electrically continuous. That is, current flows from the bit line BL to the source line SL. On the other hand, when the memory cell transistors MT connected to the selected word line WL0 are off, the bit line BL and the source line SL are electrically discontinuous. That is, no current flows from the bit line BL to the source line SL. The above-described operation allows data to be read for all the bit lines at a time.

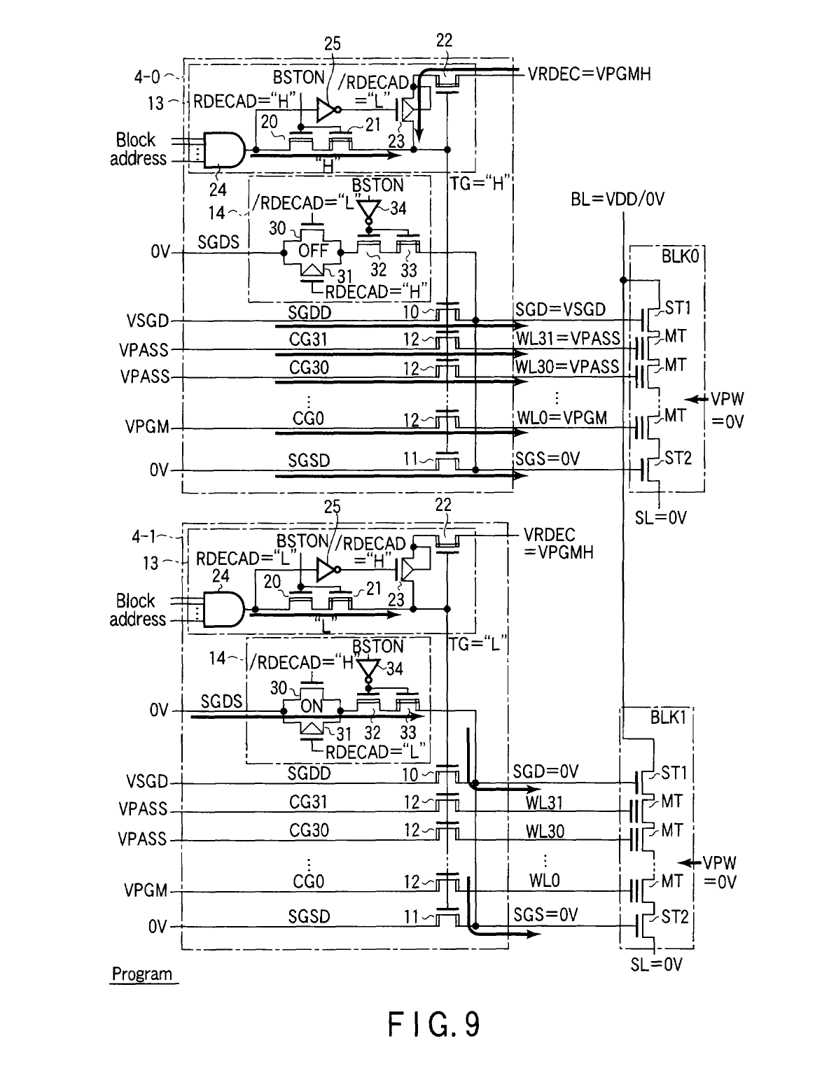

FIG. 7 is a graph showing the relationship between the read level and the voltage VCGR. FIG. 7 shows that the absolute value |V01| of the read level for “1” data is equal to VREF_SRC. As shown in FIG. 7, to read data of a negative read level, VCGR is set to a value obtained by subtracting the absolute value of the read level from VREF_SRC. To read data of a positive read level, VCGR is set to a value obtained by adding the read level to VREF_SRC. Thus, with VCGR set to a value equal to or larger than 0, the voltage of the read level can be applied to between the gate and source of the memory cell transistor MT.

Now, the row decoder 4-1, corresponding to the unselected memory block BLK1, will be described. At time t0 in FIG. 5, since the block address fails to match the memory block BLK1, to which the row decoder 4-1 corresponds, the AND gate 24 in the block decoder 13 outputs the signal RDECAD=“L”. Thus, the signal /RDECAD=“H” is set to turn off the MOS transistor 23. Furthermore, the signal BSTON=“H” is set to turn on both the n-channel MOS transistors 20 and 21 to set the signal line TG=“L” level (0V). In the transfer circuit 14, since the signal RDECAD=“L” and the signal /RDECAD=“H”, the MOS transistors 30 and 31 are turned on.

Then, at time t1, BSTON=“L” is set. In the block decoder 13, since RDECAD=“L”, the MOS transistors 20 and 21 remain on. As a result, the signal line TG maintains the “L” level (0V). Furthermore, in the transfer circuit 14, the MOS transistors 30 to 33 remain on.

Then, at time t2, the control circuit 8 sets VRDEC=VREADH. However, in the row decoder 4-1, the MOS transistor 23 is off. Thus, the voltage VREADH is not transferred to the signal line TG, which thus maintains the “L” level (0V).

Then, at time t3, the driver circuit 5 applies a voltage to each of the signal lines as described above. In this case, since TG=“L” level (0V), the MOS transistors 10 to 12 are off. Thus, the voltages applied to the signal lines CG0 to CG31, SGDD, and SGSD by the driver circuit 5 are not transferred to the word lines WL0 to WL31, SGD, and SGS, respectively. On the other hand, the voltage VREF_SRC applied to the signal SGDS by the driver circuit 5 is transferred to the select gate lines SGD and SGS via the transfer circuit 14. Thus, the potentials of the select gate lines in the unselected memory block BLK1 are set to VREF_SRC, to which the source line SL and the well region 42 are also set.

As a result, in the memory block BLK1, the select transistors ST1 and ST2 are turned off. Thus, the memory cell transistors MT in the memory block BLK1 are electrically separated from the bit lines BL.

### <Data Programming Operation>

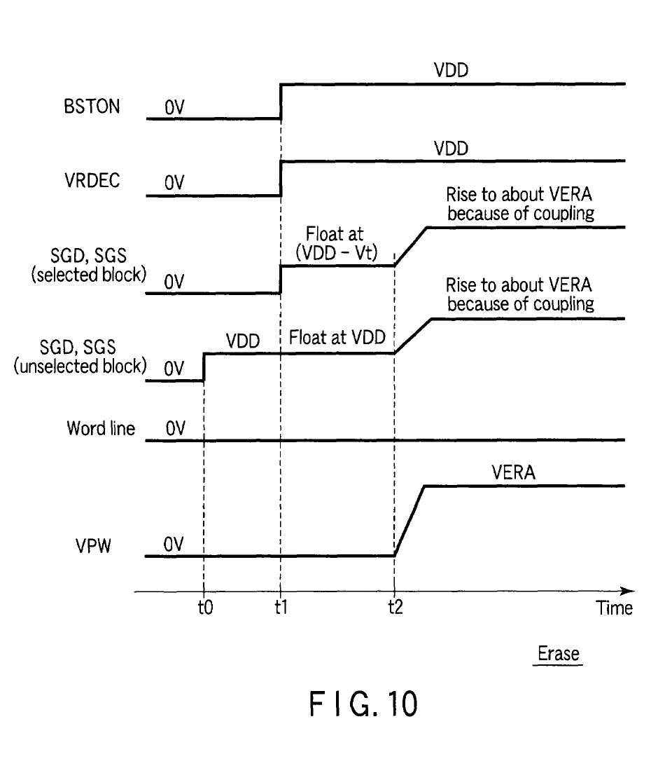

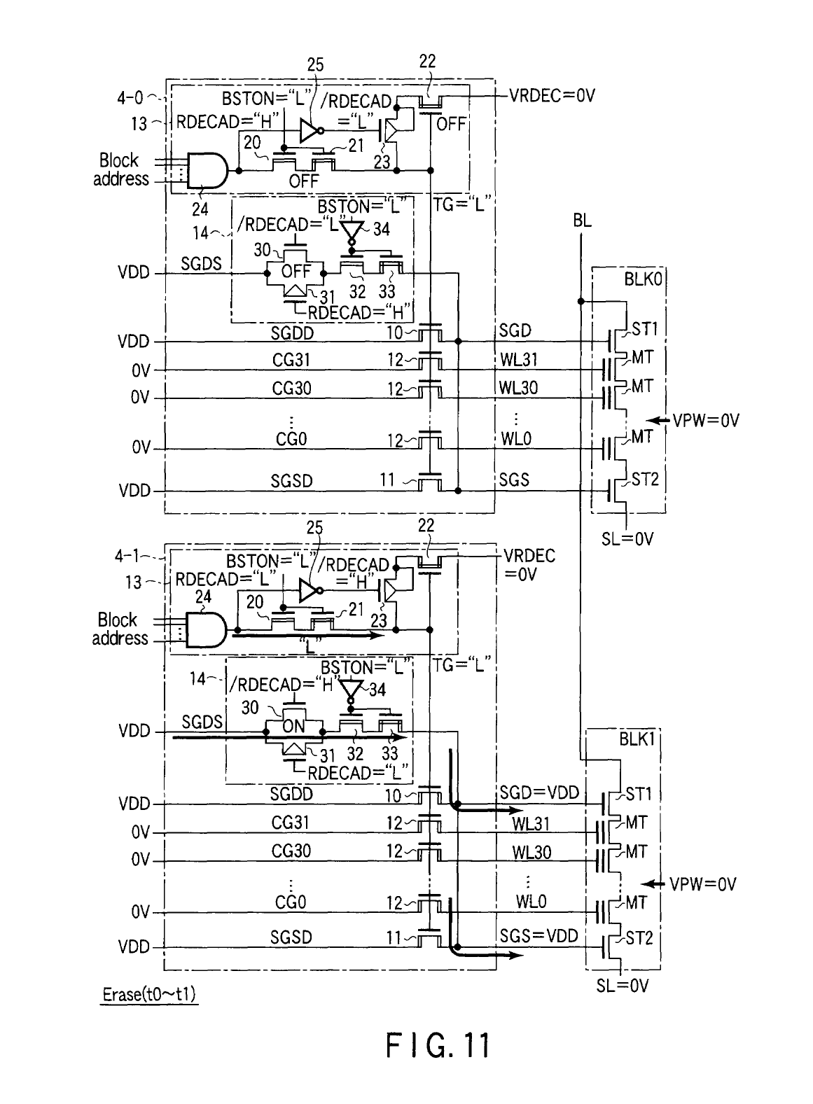

Now, the data programming operation will be described with reference to FIGS. 8 and 9. FIG. 8 is a timing chart showing variations in the potentials of the signal BSTON, the voltage VRDEC, the select gate lines SGD and SGS, and the word line WL. FIG. 7 is a circuit diagram of the row decoder 4 during the programming operation. In the description below, as in the case of the read, data is programmed in the memory cell transistors MT connected to the word line WL0 in one of the memory blocks BLK0 and BLK1, that is, the memory block BLK0, by way of example. Furthermore, because of space limitations, FIG. 9 shows only one transfer circuit 14 for each of the row decoders 4-0 and 4-1.

For the data programming, the sense amplifier 3 transfers programming data to the bit line BL. That is, to allow electrons to be injected into the charge accumulation layer to raise the threshold of the memory cell transistor MT, a write voltage (0V) is applied to the bit line BL. On the other hand, to avoid injecting electrons into the charge accumulation layer, a write inhibition voltage (for example, VDD) is applied to the bit line BL. The source line driver 7 and the well driver 6 apply 0V to the source line SL and the well region 42, respectively.

The row decoder 4-0, corresponding to the selected memory block BLK0, and the row decoder 4-1, corresponding to the unselected memory block BLK1, will be described below.

First, the row decoder 4-0, corresponding to the selected memory block BLK0, will be described. The operation of the block decoder 13 performed between time t0 and time t2 in FIG. 8 is the same as that performed between time to and time t2 during the above-described read operation. Thus, the signal line TG=“H” level (for example, VDD) is set. This turns on the MOS transistors 10 to 12. The transfer circuit 14 subsequently operates similarly. That is, the MOS transistors 30 and 31 are turned off. The select gate lines SGD and SGS are disconnected from the signal line SGDS during the programming operation.

Then, at time t2, the control circuit 8 sets VRDEC=VPGMH. The voltage VPGMH enables the MOS transistors 12 to transfer the voltage VPGM. The voltage VPGM is a high voltage (for example, 20V) that allows electrons to be injected into the charge accumulation layer 44. VPGMH is higher than VPGM at least by the threshold of the MOS transistors 22, 23, and 12. Setting VRDEC=VPGMH sets the signal line TG=VPGMH.

Then, at time t3, the driver circuit 5 applies a voltage VPASS to the signal lines CG0 to CG31, while applying the voltage VSGD and 0V to the signal lines SGDD and SGSD, respectively. The driver circuit 5 further applies 0V to the signal line SGDS. The voltage VPASS turns on the memory cell transistor MT regardless of the data held by the memory cell transistor MT. The voltage VSGD turns on the select transistor ST1 if the write voltage is applied to the bit line BL. The voltage VSGD cuts off the select transistor ST1 if the write inhibition voltage is applied to the bit line BL.

Then, since TG=VPGMH, the MOS transistors 10 and 11 transfer the voltage VSGD and 0V to the select gate lines SGD and SGS, respectively. The MOS transistors 12 transfer VPASS to the word lines WL0 to WL31.

Subsequently, at time t4, the driver circuit 5 raises the voltage applied to the signal line CG0 from VPASS to VPGM. As a result, VPGM is transferred to the word line WL0.

As a result, in the memory block BLK0, the memory cell transistors MT are turned on to form a channel. That is, current paths are formed in the memory cell transistors MT in the memory cell unit 9 and become electrically continuous. Furthermore, since 0V is applied to the select gate line SGS, the select transistor ST2 is turned off. In contrast, the select transistor ST1 is turned on or cut off depending on the programming data.

If the write voltage is applied to the bit line BL, the select transistor ST1 is turned on to transfer the write voltage to the channel of the memory cell transistor MT. Then, in the memory cell transistors MT connected to the selected word line WL0, the potential difference between the gate and channel is set almost equal to VPGM. Charges are thus injected into the charge accumulation layer. As a result, the threshold voltage of the memory cell transistor MT rises.

On the other hand, if the write inhibition voltage is applied to the bit line BL, the select transistor ST1 is cut off. Thus, the channels of the memory cell transistors MT in the memory cell unit 9 float electrically. Then, the channel potential of the memory cell transistors MT rises as a result of coupling with the gate potential (VPGM, VPASS). Thus, in the memory cell transistors MT connected to the selected word line WL0, the potential difference between the gate and the channel is insufficient. Consequently, charges are prevented from being injected into the charge accumulation layer (to the degree that the held data is changed). As a result, the threshold of each of the memory cell transistors MT remains unchanged.

Now, the row decoder 4-1, corresponding to the unselected memory block BLK1, will be described. The operations of the block decoder 13 and the transfer circuit 14 performed between time t0 and time t2 in FIG. 8 is the same as those performed between time t0 and time t2 during the above-described read operation. Thus, the signal line TG=“L” level is set. The select gate lines SGD and SGS are connected to the signal line SGDS via the transfer circuit 14.

Then, at time t2, the control circuit 8 sets VRDEC=VPGMH. However, in the row decoder 4-1, the MOS transistor 23 is off. Thus, the voltage VPGMH is not transferred to the signal line TG, which thus maintains the “L” level (0V).

Then, at time t3, the driver circuit 5 applies a voltage to each of the signal lines as described above. In this case, since TG=“L” level (0V), the MOS transistors 10 to 12 are off. Thus, the voltages applied to the signal lines CG0 to CG31, SGDD, and SGSD by the driver circuit 5 are not transferred to the word lines WL0 to WL31, SGD, and SGS, respectively 8. On the other hand, 0V applied to the signal SGDS by the driver circuit 5 is transferred to the select gate lines SGD and SGS via the transfer circuit 14.

As a result, in the memory block BLK1, the select transistors ST1 and ST2 are turned off. Thus, the memory cell transistors MT in the memory block BLK1 are electrically separated from the bit lines BL.

### <Data Erase Operation>

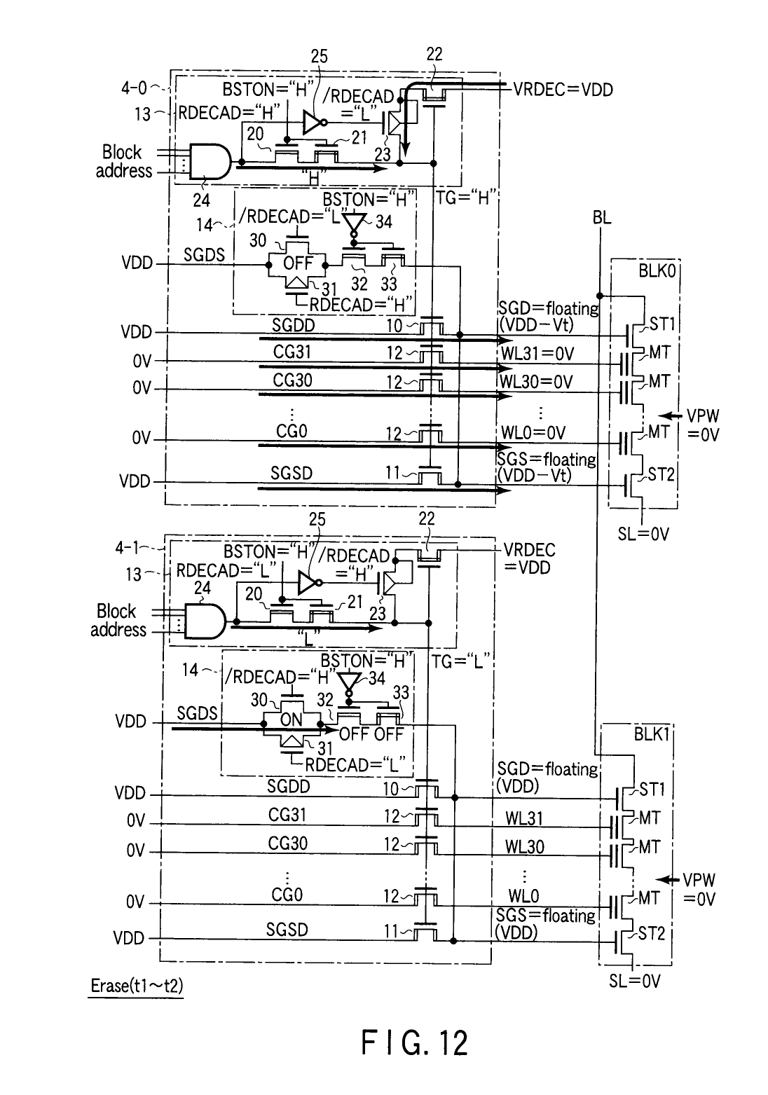

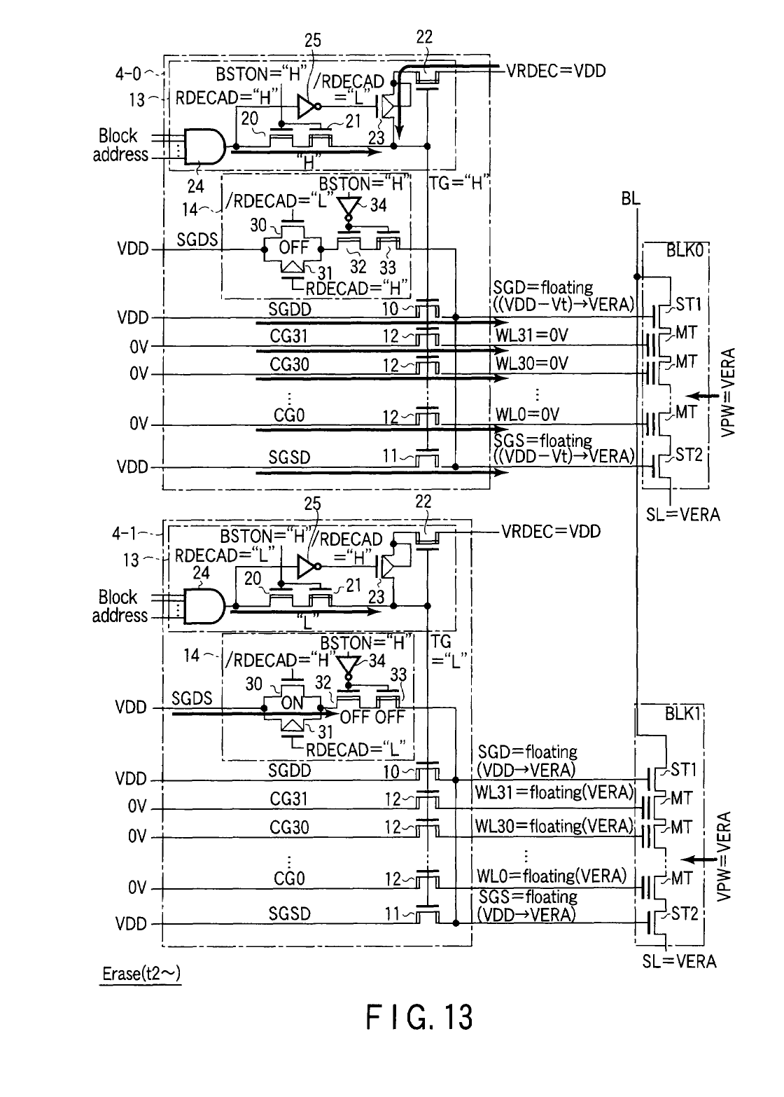

Now, the erase operation will be described with reference to FIGS. 10 to 13. FIG. 10 is a timing chart showing variations in the potentials of the signal BSTON, the voltage VRDEC, the select gate lines SGD and SGS in the selected and unselected memory blocks, the word line WL, and the well region 42 (VPW). FIGS. 11 to 13 are circuit diagrams showing how the row decoder 4 operate between time t0 and time t1, between time t1 and time t2, and during a period after time t2. In the description below, the erase operation is performed on one of the memory blocks BLK0 and BLK1, that is, the memory block BLK0, by way of example. Furthermore, because of space limitations, FIGS. 11 to 13 show only one transfer circuit 14 for each of the row decoders 4-0 and 4-1.

<<Operation Between Time t0 and Time t1>>

First, the period between time t0 and time t1 in FIG. 10 will be described with reference to FIGS. 10 and 11. To erase data, the source line driver 7 and the well driver 6 apply 0V to the source line SL and the well region 42. The driver circuit 5 applies 0V to the signal lines CG0 to CG31, while applying VDD to the signal lines SGDD, SGSD, and SGDS.

Now, the row decoder 4-0, corresponding to the selected memory block BLK0, will be described. In the row decoder 4-0, the block decoder 13 decodes the block address. Then, since the block address matches the memory block BLK0, to which the row decoder 4-0 corresponds, the AND gate 24 outputs the signal RDECAD=“H” level. Thus, the MOS transistor 23 is turned on. Furthermore, the control circuit 8 sets the signal BSTON=“L” level. Thus, both the n-channel MOS transistors 20 and 21 are turned off. In the transfer circuit 14, since the signal RDECAD=“H” and the signal /RDECAD=“L”, the MOS transistors 30 and 31 are turned off. Consequently, the select gate lines SGD and SGS are electrically disconnected from the signal SGDS. The transfer circuit 14 subsequently operates similarly. During the erase operation, the select gate lines SGD and SGS are disconnected from the signal line SGDS.

Then, the row decoder 4-1, corresponding to the unselected memory block BLK1, will be described. In the row decoder 4-1, the AND gate 24 outputs the signal RDECAD=“L” level. Thus, the MOS transistor 23 is turned off. Furthermore, since the signal BSTON=“L” level, both the n-channel MOS transistors 20 and 21 are turned on. Consequently, the signal RDECAD is transferred to the signal line TG, which is thus set to the “L” level. The MOS transistors 10 to 12 are thus turned off.

In the transfer circuit 14, the MOS transistors 30 to 33 are turned on. Therefore, the select gate lines SGD and SGS in the memory block BLK1 are electrically connected to the signal line SGDS and charged up to VDD.

<<Operation Between Time t1 and Time t2>>

Now, the period between time t1 and time t2 in FIG. 10 will be described with reference to FIGS. 10 and 12.

First, the row decoder 4-0, corresponding to the selected memory block BLK0, will be described. At time t1, the control circuit 8 sets the signal BSTON to the “H” level. Thus, in the block decoder 13, the MOS transistors 20 and 21 are turned on. Consequently, the signal RDECAD=“H” level is transferred to the signal line TG to turn on the MOS transistor 22. At this time, VRDEC is set equal to VDD. Thus, the current paths in the MOS transistors 22 and 23 also allow VDD to be transferred to the signal line TG.

As a result, the MOS transistors 12 are turned on to transfer 0V applied to the signal lines CG0 to CG31 to the word lines WL0 to WL31, respectively. The MOS transistors 10 and 11 are cut off when the select gate lines SGD and SGS are charged up to (VDD-Vt). Thus, the select gate lines SGD and SGS float at (VDD-Vt). Vt denotes the threshold voltage of the MOS transistors 10 and 11.

Now, the row decoder 4-1, corresponding to the unselected memory block BLK1, will be described. The operation of the block decoder 13 is the same performed between time t0 and time t1. Thus, the signal line TG is at 0V. Consequently, the MOS transistors 10 to 12 remain off. In the transfer circuit 14, the signal BSTON=“H” level is set to turn off the MOS transistors 32 and 33. That is, the select gate lines SGD and SGS in the memory block BLK1 are electrically disconnected from the signal line SGDS. As a result, the select gate lines SGD and SGS float at VDD.

<<Operation During the Period After t2>>

Then, the period after time t2 in FIG. 10 will be described with reference to FIGS. 10 and 13.

The operations of the row decoders 4-0 and 4-1 are the same as those performed between time t1 and time t2. At time t2, the well driver 6 applies the voltage VERA to the well region 42. The source line driver 7 also applies the voltage VERA to the source line SL.

Then, in the selected memory block BLK0, a significant potential difference occurs between the well region 42 and the word lines WL0 to WL31. Thus, the electrons in the charge accumulation layer 44 are emitted to the well region 42 to erase the data. The potentials of the select gate lines SGD and SGS rise from (VDD-Vt) up to about VERA as a result of coupling with the well region 42.

On the other hand, in the unselected memory block BLK1, the potential of the word lines WL0 to WL31 rises up to about VERA as a result of the coupling with the well region 42. Thus, the data is not erased. The potentials of the select gate lines SGD and SGS also rise from VDD to about VERA as a result of the coupling with the well region 42.

### <Effects>

As described above, the NAND flash memory according to the embodiment of the present invention exerts effects (1) and (2) described below. The effects will be described below.

### (1) Operational Reliability can be Improved (1)

The present inventors have proposed a method of applying positive voltages to the source line and the well to allow data of the negative read level to be quickly and accurately read. The present inventors have also proposed a method which relates to the above-described method and which sets the potential of the select gate line in the unselected memory block equal to that of the source line in the unselected memory block to reduce charges required to precharge the source line and the well, thus allowing the precharging to be quickly performed (Jpn. Pat. Appln. No. 2006-283457 (KOKAI Publication No. 2008-103003)).

The principle of the methods is as follows. If the select gate line in the unselected memory block is set to VSS (for example, 0V), the capacitance between the select gate line and the well needs to be charged because the select transistor in the unselected memory block is off. The total capacitance for all the memory blocks coupled to the well is very large. This increases the total amount of charges required to precharge the source line and the well.

However, if the potential of the select gate line in the unselected memory block is the same as that of the source line (to be accurate, the same as that of the well), since the select gate line and the well in the unselected memory block are at the same potential, the capacitance between the select gate line and the well need not be charged. This reduces the total amount of charge required to precharge the source line and the well. As a result, the precharging can be quickly performed.

However, if the enhancement n-channel MOS transistor of the high withstand voltage type is used as a switch to allow a potential equal to that of the source line to be transferred to the select gate line, the voltage may fail to be sufficiently transferred to the select gate line. That is, the value of the maximum voltage that can be transferred by the MOS transistor is equal to the gate voltage minus the threshold. Thus, a rise in the potential of the source line prevents the voltage from being sufficiently transferred. For example, when VDD (for example, 2.5V) is used as the gate potential of the MOS transistor, the transferable voltage is about 1.2V.

Then, if the potential of the source line exceeds 1.2V, the voltage is not completely transferred to the gate line. The MOS transistors 10 and 11 in FIG. 4 are cut off to float the select gate line. The potential of the floating select gate line rises as a result of the coupling during the precharging. As a result, in the worst case, all the memory cell units 9 in the unselected memory block may be connected to the bit line BL or an off leak current may increase, resulting in an improper read.

Thus, to avoid the above-described problem, the potential of the source line needs to be at most 1.2V, that is, the minimum value of the read level needs to be −1.2V. However, there is a demand to allow the memory cell transistor MT to hold more information (more bits), for example, data of 8 or 16 levels, and a demand to form threshold distributions at positions where acceptable data retention characteristics are exhibited. To meet these demands, the read level needs to be lower than −1.2V, that is, the potential of the source line needs to be higher than 1.2V. Thus, a method is required which not only meets the demands but also implements the above-described quick read method.

In connection with this, in the NAND flash memory according to the present embodiment, the transfer circuit 14, which transfers voltages to the select gate lines SGD and SGS, includes two switch sections. That is, the first switch section includes the high-voltage MOS transistor 33. The second switch section includes the MOS transistors 30 and 31, which has a lower withstand voltage than the first switch section.

Furthermore, the MOS transistor 33 is of the depression type, and the MOS transistors 30 and 31 are of the enhancement type. Thus, whether or not the transfer circuit 14 transfers a voltage is substantially determined by the MOS transistors 30 and 31. The MOS transistors 30 and 31 are of the low withstand voltage type and thus have a threshold voltage lower than that of the enhancement MOS transistor of the high withstand voltage type.

Consequently, even when the gate voltage (signals RDECAD and /RDECAD) is at the VDD level, the MOS transistors 30 and 31 can transfer higher voltages to the select gate lines SGD and SGS than the MOS transistor of the high withstand voltage type. For example, even if the potential of the source line is about 2V, this voltage can be transferred to the select gate lines SGD and SGS. This makes it possible not only to meet the demand to allow the memory cell transistor MT to hold more information and the demand for the threshold distribution but also to perform a quick data read by setting the potential of the select gate line in the unselected memory block equal to that of the source line in the unselected memory block.

### (2) Operational Reliability can be Improved (2).

The NAND flash memory according to the present embodiment, the transfer circuit 14 includes the high-voltage MOS transistor 33 in the first switch section. Thus, if high voltages are applied to the select gate lines SGD and SGS, the high voltages can be prevented from being applied to the low-voltage MOS transistors 30 to 32.

For example, during the data erasure, the potentials of the select gate lines SGD and SGS rise almost to the erase voltage VERA as described with reference to FIG. 13. However, at this time, the MOS transistor 33 is off. Thus, the erase voltage VERA can be prevented from being applied to the MOS transistors 30 to 32.

Thus, in the above-described embodiment, first, between time t0 and time t1, the MOS transistors 32 and 33 are turned on. The voltage VDD is then transferred to one end of the current path in the MOS transistor 33. Thereafter, the gates of the MOS transistors 32 and 33 are set to the “L” level to turn off the depression MOS transistor 33.

Furthermore, as described with reference to FIG. 10, first, the select gate lines SGD and SGS in the unselected memory block are charged between time t0 and time t1. Thereafter, between time t1 and time t2, the select gate lines SGD and SGS in the selected memory block are charged. That is, the period during which the select gate lines SGD and SGS in the unselected memory blocks are charged is different from that during which the select gate lines SGD and SGS in the selected memory blocks are charged. Thus, the present embodiment enables quicker charging than the case in which the select gate lines SGD and SGS in both unselected and selected memory blocks are simultaneously charged.

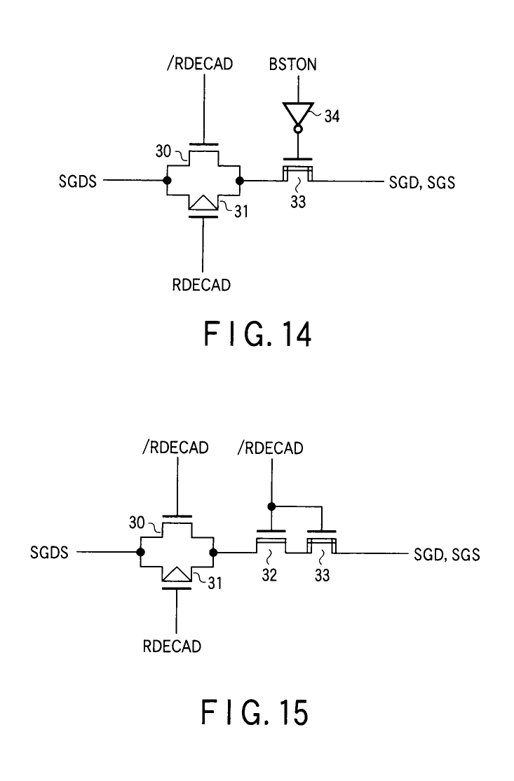

The present embodiment is not limited to the above-described embodiment. The embodiment can be varied. For example, in the above-described embodiment, the first switch section of the transfer circuit 14 includes the depression n-channel MOS transistor 32 of the high withstand voltage type in addition to the MOS transistor 33. However, as shown in the circuit diagram of the transfer circuit 14 in FIG. 14, the MOS transistor 32 may be omitted.

Furthermore, as shown in the circuit diagram of the transfer circuit 14 in FIG. 15, if there is no possibility that high voltages are applied to the MOS transistors 30 and 31, or high voltages can be applied to the MOS transistors 30 and 31 without posing any problem, the signal /RDECAD may be input to the gates of the MOS transistors 32 and 33.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a select transistor;
a memory cell transistor including a stacked gate having a charge accumulation layer and a control gate, the memory cell transistor including a current path one end of which is connected to a data transfer line via a current path in the select transistor;
a select gate line connected to a gate of the select transistor;
a word line connected to the control gate of the memory cell transistor; and
a row decoder selecting the word line and the select gate line, the row decoder including a transfer circuit configured to transfer a voltage to the select gate line, the transfer circuit including a first switch including a first MOS transistor of a depression type, the first MOS transistor including a current path one end of which is connected to the select gate line, the first MOS transistor transferring a first voltage provided to the other end of the current path to the select gate line.

2. The device according to claim 1, wherein the transfer circuit further includes a second switch including a second MOS transistor of an enhancement type, the second MOS transistor including a current path one end of which is connected to the first switch, the second MOS transistor transferring the first voltage provided to the other end of the current path to the first switch, the second MOS transistor having a lower withstand voltage than the first MOS transistor.

3. The device according to claim 1, wherein the first switch further includes a second MOS transistor of the depression type including a current path to one end of which the first voltage is provided, the other of the current path being connected to the other end of the current path in the first MOS transistor, the second MOS transistor having a lower withstand voltage than the first MOS transistor.

4. The device according to claim 1, further comprising a plurality of memory blocks each including the select transistor and the memory cell transistor, wherein the transfer circuit transfers the first voltage to the select gate line connected to the select transistor in unselected one of the memory blocks.

5. The device according to claim 4, further comprising a source line electrically connected to the other end of the current path in the memory cell transistor,
wherein during data read, a positive second voltage is applied to a semiconductor substrate on which the memory cell transistor is formed and to the source line, and
magnitude of the first voltage transferred to the select gate line by the transfer circuit is equal to that of the second voltage.

6. The device according to claim 4, wherein the row decoder further includes a second MOS transistor configured to transfer a second voltage to the word line and the select gate line in selected one of the memory blocks.

7. The device according to claim 6, wherein the row decoder further includes a block decoder controlling a gate potential of the second MOS transistor, and
the block decoder includes:
a decode section decoding an address for the memory bock; and
a third MOS transistor transferring a third voltage to a gate of the second MOS transistor according to a decode result of the decode section.

8. The device according to claim 6, wherein the transfer circuit and the second MOS transistor are provided in association with each of the memory blocks,
during data read, data write, and data erasure, the first MOS transistor in the transfer circuit and the second MOS transistor corresponding to the selected one of the memory blocks are turned off and turned on, respectively, and
the first MOS transistor in the transfer circuit and the second MOS transistor corresponding to the unselected one of the memory blocks are turned on and turned off, respectively.

9. The device according to claim 6, wherein during a data erase operation, the first MOS transistor is turned on, and the second MOS transistor is then turned on.

10. The device according to claim 1, wherein the memory cell transistor is configured to hold data of at least four levels.

11. A semiconductor memory device comprising:
a select transistor;
a memory cell transistor including a stacked gate including a charge accumulation layer and a control gate, the memory cell transistor including a current path one end of which is connected to a data transfer line via a current path in the select transistor, the memory cell transistor being configured to hold data;
a plurality of memory blocks each including the select transistor and the memory cell transistor, the data held by the memory cell transistor being erased in units of the memory blocks;
a select gate line connected to a gate of the select transistor;
a word line connected to the control gate of the memory cell transistor; and
a first MOS transistor of a depression type provided in association with each of the memory blocks, the first MOS transistor being configured to transfer a first voltage to the select gate line connected to the select transistor in the corresponding one of the memory blocks, the first MOS transistor transferring the first voltage when the memory cell transistor in the corresponding one of the memory blocks is nontarget for read, write, or erasure of the data.

12. The device according to claim 11, further comprising a second MOS transistor of an enhancement type including a current path one end of which is connected to one end of the current path in the first MOS transistor, the first voltage being applied to the other end of the current path, the second MOS transistor having a lower withstand voltage than the first MOS transistor,
wherein the other end of the current path in the first MOS transistor is connected to the corresponding select gate line.

13. The device according to claim 11, further comprising a second MOS transistor of the depression type including a current path one end of which is connected to one end of the current path in the first MOS transistor, the first voltage being applied to the other end of the current path, the second MOS transistor having a lower withstand voltage than the first MOS transistor,
wherein the other end of the current path in the first MOS transistor is connected to the corresponding select gate line.

14. The device according to claim 11, further comprising a source line electrically connected to the other end of the current path in the memory cell transistor,
wherein during data read, a positive second voltage is applied to a semiconductor substrate on which the memory cell transistor is formed and to the source line, and
magnitude of the first voltage transferred to the select gate line by the first MOS transistor is equal to that of the second voltage.

15. The device according to claim 11, further comprising a second MOS transistor configured to transfer a second voltage to the word line and the select gate line in one of the memory blocks which is a target for read, write, or erasure of the data.

16. The device according to claim 15, further comprising a block decoder controlling a gate potential of the second MOS transistor, and
the block decoder includes:
a decode section decoding an address for the memory bock; and
a third MOS transistor transferring a third voltage to a gate of the second MOS transistor according to a decode result of the decode section.

17. The device according to claim 15, wherein the first and second MOS transistors are provided in association with each of the memory blocks,
the first MOS transistor and the second MOS transistor corresponding to one of the memory blocks which is target for read, write, or erasure of the data are turned off and turned on, respectively, and
the first MOS transistor and second MOS transistor corresponding to one of the memory blocks which is nontarget for read, write, or erasure of the data are turned on and turned off, respectively.

18. The device according to claim 15, wherein during a data erase operation, the first MOS transistor is turned on, and the second MOS transistor is then turned on.

19. The device according to claim 11, wherein the memory cell transistor is configured to hold data of at least four levels, and
threshold levels of data of a plurality of the four levels have negative values.
